(19) United States
(12) Patent Application Publication
(10) Pub. No.: US 2026/0371616 A1
(43) Pub. Date: Nov. 19, 2026

(54) HIGH-BANDWIDTH MEMORY DEVICES HAVING AN INTEGRATED THERMOELECTRIC DIE AND ASSOCIATED SYSTEMS AND METHODS

(71) Applicant: Micron Technology, Inc., Boise, ID (US)

(72) Inventors: Daniel Penney, Wylie, TX (US); Raghukiran Sreeramaneni, Frisco, TX (US)

(21) Appl. No.: 19/655,553

(22) Filed: Apr. 22, 2026

Related U.S. Application Data
(60) Provisional application No. 63/805,087, filed on May 13, 2025.

(51) Int. Cl. H10B 80/00; H10W 40/28; H10W 90/00; H10W 90/20; H10W 90/26

(52) U.S. Cl. CPC H10B 80/00; H10W 40/28; H10W 90/26; H10W 90/288; H10W 90/297; H10W 90/722

(57) ABSTRACT

System-in-package (SiP) devices and high-bandwidth memory (HBM) devices that include features to help manage heat, and associated systems and methods, are disclosed herein. For example, an HBM device according to the present disclosure can include a base die, a thermoelectric die integrated with the base die, and a stack of memory dies integrated with the thermoelectric die. The HBM device can also include one or more first through substrate vias (TSVs; e.g., thermal TSVs) that extend from an uppermost surface of the stack of memory dies to the thermoelectric dies and a plurality of second TSVs (e.g., signal TSVs) extending from the base die to an uppermost die in the stack of memory dies. The thermoelectric die can include a thermoelectric circuit that can move heat from the base die into the first TSVs to provide active cooling to the base die.

### CROSS-REFERENCE TO RELATED APPLICATIONS

The present application claims priority to U.S. Provisional Patent Application No. 63/805,087, filed May 13, 2025, the disclosure of which is incorporated herein by reference in its entirety.

### TECHNICAL FIELD

The present technology is generally directed to heat management in vertically stacked semiconductor devices and more specifically to systems and methods for integrating a thermoelectric die into high-bandwidth memory devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or addressing increases in operating temperatures with increasing density.

### BRIEF DESCRIPTION OF THE DRAWINGS

FIG. 1 is a schematic diagram illustrating an environment that incorporates a high-bandwidth memory architecture.

FIG. 2 is a partially schematic cross-sectional diagram of a system-in-package with a high-bandwidth memory device.

FIG. 3 is a partially schematic diagram of an example of a thermoelectric device.

FIG. 4 is a partially schematic cross-sectional diagram of a high-bandwidth memory device configured in accordance with embodiments of the present technology.

FIG. 5A is a partially schematic cross-sectional diagram of a portion of a high-bandwidth memory device illustrating details of a thermoelectric circuit in accordance with embodiments of the present technology.

FIG. 5B is a partially schematic top view of a thermoelectric die for a high-bandwidth memory device configured in accordance with embodiments of the present technology.

FIG. 6 is a partially schematic cross-sectional diagram of a portion of a high-bandwidth memory device illustrating details of a thermoelectric circuit in accordance with further embodiments of the present technology.

FIG. 7 is a partially schematic cross-sectional diagram of a portion of a high-bandwidth memory device illustrating details of a thermoelectric circuit in accordance with further embodiments of the present technology.

FIG. 8 is a partially schematic cross-sectional diagram of a portion of a high-bandwidth memory device illustrating details of a thermoelectric circuit in accordance with further embodiments of the present technology.

FIG. 9 is a partially schematic cross-sectional diagram of a high-bandwidth memory device configured in accordance with embodiments of the present technology.

FIG. 10 is a partially schematic cross-sectional diagram of a high-bandwidth memory device configured in accordance with embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

System-in-package (SiP) devices and high-bandwidth memory (HBM) devices that include features to help manage heat, and associated systems and methods, are disclosed herein. For example, as discussed in more detail below, an HBM device according to the present disclosure can include a base die, a thermoelectric die integrated with the base die, and a stack of memory dies integrated with the thermoelectric die. The HBM device can also include one or more first through substrate vias (TSVs) (e.g., thermal TSVs) that extend from an uppermost surface of the stack of memory dies to the thermoelectric die and a plurality of second TSVs (e.g., signal TSVs) extending from the base die to an uppermost die in the stack of memory dies. The thermoelectric die can include a thermoelectric circuit that has a first side thermally coupled to the base die and a second side opposite the first side thermally coupled to the first TSVs such that the thermoelectric circuit moves heat from the base die into the first TSVs when a current is applied to the thermoelectric circuit. As a result, the thermoelectric die can provide active cooling to the base die while expelling heat through the first TSVs (e.g., through the thermal TSVs, separate from the second, signal TSVs), thereby reducing an operating temperature of the HBM device.

Although the systems and methods discussed herein are discussed primarily with reference to mitigating heat in an HBM device separate from the processing unit (e.g., a “2.5D HBM device”), one of skill in the art will understand that the processes of the present technology discussed herein are not so limited. Purely by way of example, the thermoelectric circuit and associated features disclosed herein can be implemented in a 3D HBM device (e.g., memory dies stacked directly on the processing unit) to help transport heat away from the processing unit peripheral to the memory dies. In this example, the 3D HBM device can include a thermoelectric die of the type disclosed herein between the processing unit and the memory dies. Further, the 3D HBM device includes one or more thermal TSVs extending through the memory dies to transport heat through the memory dies and to an outermost surface for dissipation. Additionally, or alternatively, one of skill in the art will understand that the thermoelectric die and associated features can be deployed in various other semiconductor settings to help transport heat away from hot circuits peripheral to other dies and/or circuits.

As used herein, the terms “vertical,” “lateral,” “upper,” “lower,” “top,” and “bottom” can refer to relative directions or positions of features in the HBM devices (and SiP devices more generally) in view of the orientation shown in the drawings. For example, “bottom” can refer to a feature positioned closer to the bottom of a page than another feature. These terms, however, should be construed broadly to include HBM devices (and SiP devices) having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Further, unless the context indicates otherwise, structures disclosed herein can be formed using one or more semiconductor manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques.

High data reliability, high speed of memory access, lower power consumption, and reduced chip size are features that are demanded from semiconductor memory. In recent years, stacked memory devices (e.g., three-dimensional (3D) memory devices) have been introduced. Some stacked memory devices are formed by stacking memory dies vertically on a base die (e.g., a “2.5D memory device”), and interconnecting the dies using through-silicon (or through-substrate) vias (TSVs). Some stacked memory devices are formed by stacking memory dies vertically directly on a processing unit (e.g., “3D memory device”) and interconnecting the dies using TSVs. Benefits of the stacked memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D and 3D memory devices contribute to higher memory access speed, lower power consumption, and chip size reduction. Examples of stacked memory devices include Hybrid Memory Cube (HMC) and High-Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a SiP device configuration, HBM devices may be integrated with a host device (e.g., a graphics processing unit (GPU), computer processing unit (CPU), and/or another suitable processing unit) using a base substrate (e.g., a silicon interposer, a substrate of organic material, a substrate of inorganic material and/or any other suitable material that provides interconnection between CPU/GPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device (and the silicon interposer integrating HBM devices and a host device) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., CPU/GPU) and HBM devices during operation. For example, the high-bandwidth channels can be on the order of 1000s of gigabytes per second (GB/s, sometimes also referred to as gigabits (Gb)). It will be appreciated that such high-bandwidth data transfer between a CPU/GPU and the memory of HBM devices can be advantageous in various high-performance computing applications, such as video rendering, high-resolution graphics applications, artificial intelligence and/or machine learning (AI/ML) computing systems and other complex computational systems, autonomous control of vehicles, and/or various other computing applications.

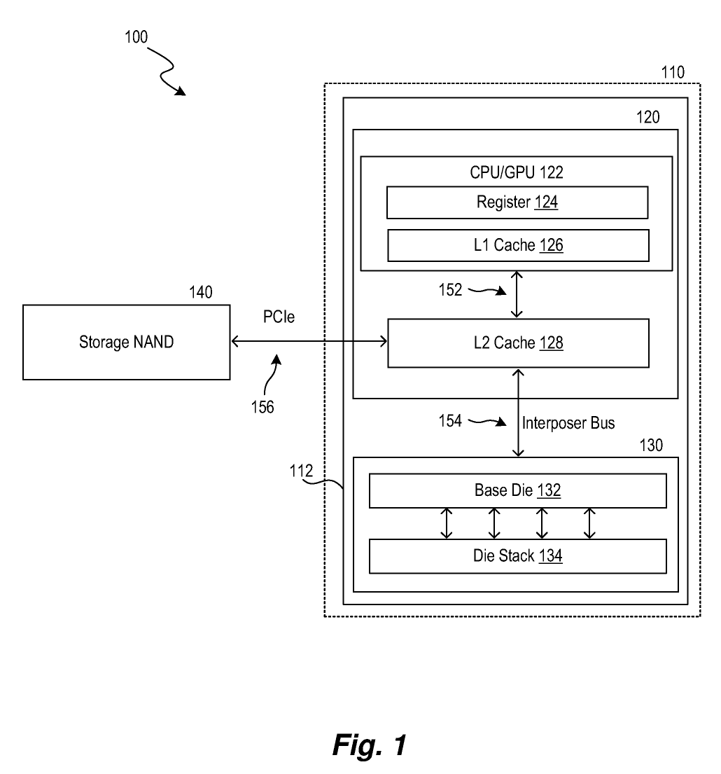

FIG. 1 is a schematic diagram illustrating an environment 100 that incorporates a high-bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing device(s) 120 can include one or more processing units 122 (e.g., one or more CPUs, one or more GPUs, and/or the like), each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and the processing units 122 therein). During operation of the SiP device 110, the processing units 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 (and L2 cache 128 therein) and HBM device(s) 130 are carried by and electrically coupled (e.g., integrated by) the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110 and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during the operation of the SiP device 110, the processing device(s) 120 can read data from and/or write data to the HBM device(s) 130 and/or the storage device 140, through the L2 cache 128.

In the illustrated environment 100, the HBM device(s) 130 each include a base die 132 and a die stack 134 communicably coupled to the base die 132. The base die 132 can include a PHY that is communicably coupled to the second communication channel 154. The PHY can receive signals from the processing device(s) 120 via the second communication channel 154 and route the signals to the die stack 134. The die stack 134 can include one or more memory dies (e.g., DRAM dies, other volatile memory dies, and/or the like) that are each communicably coupled to the PHY in the base die 132.

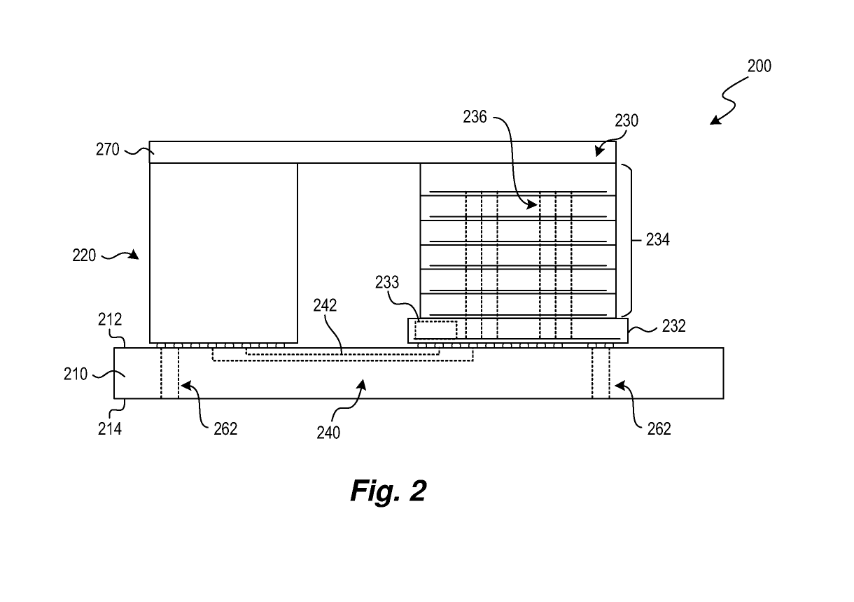

FIG. 2 is a partially schematic cross-sectional diagram of a SiP 200 that can be employed in the environment 100 discussed above with reference to FIG. 1. As illustrated in FIG. 2, the SiP 200 includes a base substrate 210 (e.g., a silicon interposer, another organic interposer, an inorganic interposer, and/or any other suitable base substrate), as well as a processing device 220 and an HBM device 230 each integrated with an upper surface 212 of the base substrate 210.

As a result, the processing device 220 can be coupled to the HBM device 230 through a high-bandwidth bus 240 that includes a substrate bus 242. For example, the processing device 220 and the HBM device 230 can each be coupled to various route lines in the substrate bus 242 via solder structures (e.g., solder balls), metal-metal bonds, and/or any other suitable conductive bonds. The route lines of the substrate bus 242, in turn, can include one or more metallization layers formed in one or more RDL layers of the base substrate 210 and/or one or more vias interconnecting the metallization layers. As a result, components of the HBM device 230 and the processing device 220 can communicate data at a relatively high rate (e.g., on the order of 1000s of GB/s).

Further, as illustrated in FIG. 2, the base substrate 210 can include one or more external TSVs 262 (four illustrated in FIG. 2) that extend from the upper surface 212 of the base substrate 210 to a lower surface 214 of the base substrate 210. The external TSVs 262 can couple the processing device 220, the HBM device 230, and/or the substrate bus 242 to package interconnects (e.g., solder structures, bond pads, and/or the like) on the lower surface. In turn, the package interconnects can be coupled to an external substrate (e.g., a package substrate), thereby communicably coupling the processing device 220, the HBM device 230, and/or the substrate bus 242 to various external components.

In the environment illustrated in FIG. 2, the processing device 220 is illustrated as a single package/component. It will be understood, however, that the processing device 220 can include a variety of components, such as a processing unit (e.g., a CPU/GPU), one or more registers, an L1 cache, an L2 cache, and/or any other suitable components. In contrast, FIG. 2 illustrates a variety of specific components of the HBM device 230. For example, the HBM device 230 includes a base die 232 and one or more memory dies 234 (six illustrated in FIG. 2) integrated with (e.g., carried by and electrically coupled to) the base die 232. The base die 232 (sometimes also referred to herein as an “interface die”) includes a PHY 233 and one or more metallization layers communicably coupled to the PHY 233. Each of the memory dies 234 (e.g., DRAM dies) includes a plurality of TSVs 236 (and a plurality of bonding features such as metal-metal bonded pads, solder structures, and/or the like coupling the TSVs 236, sometimes referred to collectively as an “HBM bus”) that establish a communication path between the base die 232 and each of the memory dies 234. As a result, the PHY 233 can route signals to (and receive signals from) each of the memory dies 234 through the HBM bus.

In an example of operation of the SiP 200, the processing device 220 can request information stored in the HBM device 230 through the substrate bus 242. The request is received by the PHY 233 of the base die 232. The PHY 233 then determines which of the memory dies 234 to request information from to satisfy the request from the processing device 220 (e.g., identifies which of the memory dies 234 stores the requested information). The PHY 233 then prompts the identified memory dies to forward the information via the HBM bus. The PHY 233 then receives the information (or an error signal) in response and forwards the information (or the error) back to the processing device 220. Operations according to the example above can share information at relatively high rates (e.g., up to an order of 1000s of GB/s), with each of the signals needing to be routed through the PHY 233. As a result, the PHY 233 can generate a substantial amount of heat. Unmitigated, the heat can elevate temperatures in the HBM device 230, thereby causing various deleterious effects in the HBM device 230, particularly within the memory dies 234. For example, the elevated temperatures can cause data loss in the memory dies 234, thereby requiring increased refresh rates to avoid errors. In turn, the increased refresh rates increase power demands for the SiP 200 and slow down processing power overall.

Accordingly, it is advantageous to dissipate the heat away from the HBM device 230 (and/or the SiP 200 more broadly) to help avoid the deleterious effects. To help dissipate the heat, as further illustrated in FIG. 2, the SiP 200 can include a thermal lid 270 that is carried by an uppermost surface of the processing device 220 and a topmost surface of the HBM device 230 (e.g., an upper surface of an uppermost memory die). During operation, heat from the PHY 233 is inadvertently communicated through the memory dies 234 (e.g., via the TSVs 236) and into the thermal lid 270. The heat is then dissipated, helping keep the base die 232 and/or each of the memory dies 234 below a threshold temperature.

As demands for the SiP 200 increase, however, the number of the memory dies 234 and/or communication routes (e.g., the number of the TSVs 236 in the HBM bus and/or the like) is increased. While the increased number of the memory dies 234 and/or the increased number of channels can help expand the overall capacity and/or the communication bandwidth within the SiP 200, the increases are associated with corresponding increases in the amount of heat generated in the PHY 233. The increases in heat generation, in turn, threaten the deleterious effects discussed above.

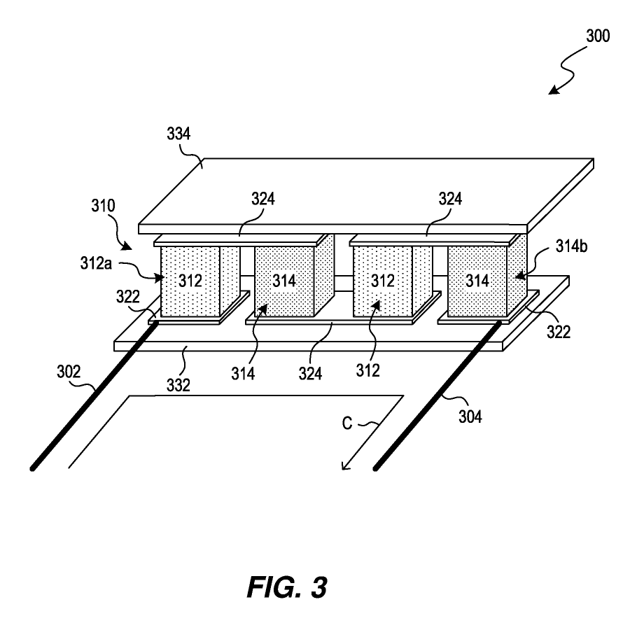

FIG. 3 is a partially schematic diagram of an example of a thermoelectric device 300. As illustrated in FIG. 3, the thermoelectric device 300 includes a series of semiconductor elements 310 that are coupled in series. More specifically, the semiconductor elements 310 alternate between a first element 312 (e.g., a pellet of an n-type semiconductor material) and a second element 314 (e.g., a pellet of a p-type semiconductor material). The first-first semiconductor element 312a is electrically coupled to a first wire 302 via a first electrical connection 322. The first electrical connection 322 is an electrically and thermally conductive material (e.g., a metal such as copper, gold, and/or the like). Similarly, a last-second semiconductor element 314b is coupled to a second wire 304 via a first electrical connection 322. Further, each of the first and second elements 312-314 is coupled to adjacent ones of the first and second elements 312-314 in the series by a second electrical connection 324, thereby establishing the series of the semiconductor elements 310. Similar to the first electrical connection 322, the second electrical connection 324 is an electrically and thermally conductive material (e.g., a metal such as copper, gold, and/or the like).

As further illustrated in FIG. 3, the semiconductor elements 310 are positioned between a first plate 332 and a second plate 334. The first and second plates 332-334 are thermally conductive, but not electrically conductive (e.g., a ceramic material). As a result, the first and second plates 332-334 can be thermally coupled to (e.g., in physical contact with) the first and second electrical connections 322-324 without forming a short circuit in the series of the semiconductor elements 310. As a result, a current can be passed through the semiconductor elements 310 in series (e.g., alternating between the first and second elements 312-314), for example along current path C.

As the current passes through the different semiconductor elements, heat is generated at one junction and absorbed at the other junction via the Peltier effect. As a result, the thermoelectric device 300 can provide active cooling at the first plate 332 while expelling heat through the second plate 334 (when the current runs opposite to path C) and/or can provide active cooling at the second plate 334 while expelling heat through the first plate 332 (when the current runs along path C). Said another way, the Peltier effect allows the thermoelectric device 300 to transport heat between the first and second plates 332-334 depending on the direction of the current.

While the Peltier effect can provide active cooling in a variety of settings, the thermoelectric device 300 of FIG. 3 is generally incompatible with an HBM device of the type discussed above with reference to FIG. 2. For example, a thermoelectric device attached to the outside of the HBM device (e.g., on top of the memory dies) would be spaced apart from the heat-generating components (e.g., the PHY) in the HBM device, thereby undermining the efficacy of the active cooling. Furthermore, the thermoelectric device 300 of FIG. 3 cannot be mounted within the HBM device. For example, the thousands (or tens of thousands) of signals that are routed through HBM devices cannot pass through the ceramic material in the first and second plates 332-334 of thermoelectric device 300. Further, the combination of ceramic plates (e.g., the first and second plates 332-334) and pellets (e.g., the first and second elements 314-312) are generally too thick to comply with industry requirements for HBM heights.

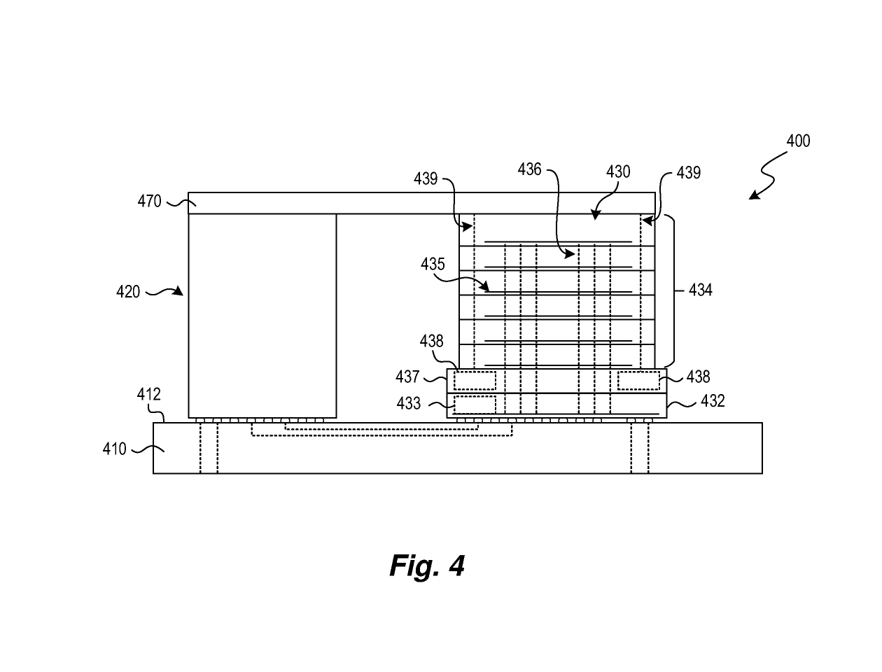

HBM devices, and associated systems and methods, that incorporate thermoelectric devices to help the challenges posed by heat generation in the PHY and other thermal hotspots of HBM devices discussed above are disclosed herein. For example, FIG. 4 is a partially schematic cross-sectional diagram of a SiP device 400 configured in accordance with embodiments of the present technology. As illustrated in FIG. 4, the SiP device 400 is generally similar to the SiP device discussed above with reference to FIG. 2. For example, the SiP device 400 includes a base substrate 410, a processing device 420 and an HBM device 430 each integrated with an upper surface 412 of the base substrate 410, and a thermal lid 470 carried by the processing device 420 and the HBM device 430.

Further, the HBM device 430 includes a base die 432 and one or more memory dies 434 (six illustrated in the cross-section of FIG. 4) carried by the base die 432. Still further, the base die 432 includes a PHY 433 that is communicably coupled to each of the memory dies 434 (sometimes referred to collectively herein as a “memory die stack,” a “stack of memory dies,” and/or the like) via a plurality of signal TSVs 436 (e.g., an HBM bus). Similar to the discussion above, each of the signal TSVs 436 in the HBM bus can include a segment in each of the memory dies 434 that are coupled together via a plurality of bonding features (e.g., bond sites (e.g., copper pads, gold-plated pads, exposed pads, and/or the like) bonded via metal-metal bonds, solder structures (e.g., solder balls, solder pillars, and/or the like), and/or the like) between corresponding segments of the signal TSVs 436 in the memory dies 434.

In the illustrated embodiments, the HBM device 430 further includes a thermoelectric die 437 (carried by the base die 432 and beneath the memory dies 434) and one or more thermal TSVs 439 (two illustrated in the cross-section of FIG. 4). The thermoelectric die 437 includes one or more thermoelectric circuits 438 (two illustrated in the cross-section of FIG. 4) formed directly into (e.g., integrated with) the substrate of the thermoelectric die 437. Additionally, the thermoelectric die 437 includes a lower portion (e.g., lower segments) of the signal TSVs 436 spaced laterally apart from the thermoelectric circuits 438. Similar to the discussion above, the thermoelectric circuits 438 can each transport heat from a first side of the circuit to a second side of the circuit in response to an input (e.g., a drive) current through the thermoelectric circuits 438. Said another way, each of the thermoelectric circuits 438 can provide active cooling to one side of the circuit while expelling heat at the other side of the circuit. For example, a lower side of the thermoelectric circuits 438 (in the illustrated orientation) can provide active cooling to the base die 432 while the upper side expels heat. In turn, the thermal TSVs 439 can be thermally coupled between the upper side of the thermoelectric circuits 438 and the thermal lid 470. As a result, the thermal TSVs 439 can transport the expelled heat away from the thermoelectric circuits 438 and into the thermal lid 470. That is, the thermoelectric circuits 438 can transport heat from the base die 432 into the thermal TSVs 439 and the thermal TSVs 439 can then transport the heat to the thermal lid 470. As a result, the thermoelectric die 437 can provide active cooling to the base die 432 to help counter and/or mitigate the heat generated by heat-generating areas of the base die 432, such as the PHY 433. In turn, the thermoelectric die 437 can help reduce and/or mitigate the thermal buildup in the HBM device 430, and memory dies 434 therein, during operation of the SiP device 400.

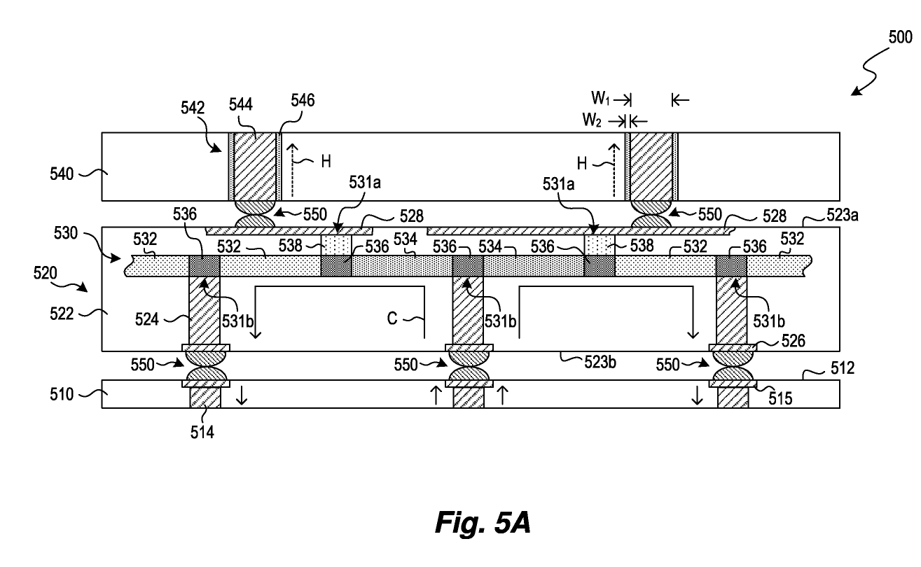

As further illustrated in FIG. 4, the thermoelectric circuits 438 and/or the thermal TSVs 439 can be positioned to at least partially vertically overlap with the PHY 433 in the base die 432. The vertical overlap can help increase the amount of heat communicated through the thermoelectric circuits 438 and into the thermal TSVs 439 and/or reduce the amount of heat communicated through a core of the memory dies 434. As a result, the vertical overlap can further help counter and/or mitigate the heat generated by the PHY 433 as the density in the HBM device 430 increases. Said another way, the vertical overlap can further help reduce and/or mitigate the thermal buildup in the memory dies 434 during operation of the SiP device 400. Additionally, or alternatively, the thermal TSVs 439 can be spaced apart and/or insulated from the signal TSVs 436 and/or memory circuits 435 in the memory dies 434, thereby thermally and electrically isolating the thermal TSVs 439. The isolation, in turn, can help reduce the amount of heat that leaks out of the thermal TSVs 439 and into the memory circuits 435 (and/or the core of the memory dies 434), thereby further helping mitigate thermal buildup in the memory dies 434 during operation of the SiP device 400. In some embodiments, the thermoelectric circuits 438 are distributed throughout the thermoelectric die 437 (e.g., additional thermoelectric circuits can be positioned between the thermoelectric circuits 438 illustrated in FIG. 4 and the signal TSVs 438). In such embodiments, the thermoelectric circuits that are not directly coupled to and/or aligned with one of the thermal TSVs 439 can be thermally coupled to one or more of the thermal TSVs 439 via one or more metal routing layers in the thermoelectric die 437. Additional details on the thermoelectric die 437, the thermoelectric circuits 438, and the thermal TSVs 439 according to various embodiments of the present technology are discussed below with reference to FIG. 5A–8.

FIG. 5A is a partially schematic cross-sectional diagram of a portion of an HBM device 500 illustrating details of a thermoelectric circuit 530 in accordance with embodiments of the present technology. In the illustrated cross-section, the HBM device 500 includes a base die 510, a thermoelectric die 520 carried by the base die 510, and a memory die 540 carried by the thermoelectric die 520. The thermoelectric circuit 530 is formed in a base substrate 522 (e.g., a thermally and electrically non-conductive substrate, such as a silicon substrate) of the thermoelectric die 520. For example, the thermoelectric circuit 530 includes an array of semiconductor elements that include one or more first elements 532 (four shown in the cross-section of FIG. 5A) and one or more second elements 534 (two shown in the cross-section of FIG. 5A). For example, the first elements 532 are regions of the base substrate 522 that are doped with a first type of semiconductor material (e.g., doped with an n-type semiconductor material), while the second elements 534 are regions of the base substrate 522 that are doped with a second type of semiconductor material (e.g., doped with a p-type semiconductor material).

The thermoelectric circuit 530 also includes bridge regions 536 formed between each adjacent pair of the first elements 532 and/or the second elements 534 (e.g., between two adjacent first elements 532, between two adjacent second elements 534, and between adjacent first and second elements 532-534). The bridge regions 536 (sometimes also referred to herein as “contact regions”) include a thermally and electrically conductive material (e.g., copper, aluminum, Cubic Boron Arsenide, and/or the like formed into a nanowire between the adjacent pairs, metal route lines, metallic-doped silicon, and/or the like), thereby allowing electricity and/or heat to pass between the adjacent elements. As further illustrated in FIG. 5A, the thermoelectric circuit 530 can further include one or more thermal bridge regions 538 (two illustrated in the cross-section of FIG. 5A) that are each coupled to the bridge region between opposite thermocouple pairs of the first and second elements 532-534. The thermal bridge regions 538 include a thermally conductive and electrically non-conductive material (e.g., diamond, diamond-doped silicon, Aluminum Nitride, Boron Nitride, and/or the like). As a result, the first and second elements 532-534 can form thermocouple pairs that are thermally coupled to the thermal bridge regions 538. The thermal bridge regions 538, in turn, provide a thermal contact at a first side 531a of the thermoelectric circuit 530 where heat can be expelled (or absorbed) while helping prevent a current from leaking out of the thermoelectric circuit 530. That is, when a current is passed between corresponding pairs of the first and second elements 532-534, thermoelectric circuit 530 can move heat (based on the Peltier effect) between the first side 531a and a second side 531b of the thermoelectric circuit 530 (e.g., a lowermost contact of the thermoelectric circuit 530, such as lower surfaces of the bridge regions between adjacent pairs of the first elements 532 and/or between adjacent pairs of the second elements 534).

In various embodiments, the current for the thermoelectric circuit can be provided directly from the base die 510 or through the memory die 540 (e.g., via a metallization layer formed in a lowermost memory die in the die stack and/or through a plurality of memory dies in the die stack). Further, in various embodiments, the thermoelectric circuit 530 can be formed adjacent to an upper surface 523a of the base substrate 522 and/or a lower surface 523b of the base substrate 522. Said another way, the thermoelectric die 520 can be integrated with the base die in a face-to-face configuration (e.g., with the thermoelectric circuit 530 adjacent to the lower surface 523b) or a face-to-back configuration (e.g., with the thermoelectric circuit 530 adjacent to the upper surface 523a). In each of the embodiments discussed above, the thermoelectric circuit 530 and/or the thermoelectric die 520 can include various other features to form thermal and/or electrical connections between the thermoelectric circuit 530 and the upper and lower surfaces 523a, 523b. As a result, the thermoelectric circuit 530 can transport heat between the lower surface 523b (and portions of the base die 510 thermally coupled thereto) and the upper surface 523a (and portions of the memory die 540 thermally coupled thereto).

In the embodiments illustrated in FIG. 5A, the thermoelectric die 520 is integrated with the base die 510 in a face-to-back configuration and the thermoelectric circuit 530 is powered directly from the base die 510. For example, the base die 510 includes an upper surface 512, two or more first power TSVs 514 (three illustrated in the cross-section of FIG. 5A), and a bond site 515 formed at the upper surface 512 for each of the first power TSVs 514. Similarly, the thermoelectric die 520 includes two or more bond sites 526 (three illustrated in the cross-section of FIG. 5A) formed at the lower surface 523b and a second power TSV 524 extending from each of the bond sites 526 to a corresponding one of the bridge regions 536. That is, the second power TSVs conductively couple corresponding ones of the bridge regions 536 to the bond sites 526. As a result, the first and second power TSVs 514-524 (and the conductive structures coupled therebetween) allow the base die 510 to direct a current through the thermoelectric circuit 530, for example along current paths C.

In the illustrated embodiment, the bond sites 515 of the base die are coupled to the bond sites 526 of the thermoelectric die 520 via conductive structures 550. The conductive structures 550 can include solder structures (e.g., solder balls, solder pillars, and/or the like), microbumps, conductive pillars (e.g., copper pillars, gold pillars, and/or the like), and/or any other suitable component. In some embodiments, the bond sites 515 of the base die are directly coupled to the bond sites 526 of the thermoelectric die 520 via metal-metal bonds.

As further illustrated in FIG. 5A, the thermal bridge regions 538 are positioned between the thermoelectric circuit 530 and the upper surface 523a of the thermoelectric die 520. As a result, the thermal bridge regions 538 help electrically isolate the thermoelectric circuit 530 from the upper surface 523a of the thermoelectric die 520 while providing a thermal pathway between the thermoelectric circuit 530 and the upper surface 523a. Said another way, the thermal bridge regions 538 allow the thermoelectric circuit 530 to transport heat to the upper surface 523a of the thermoelectric die 520 without leaking current out of the thermoelectric circuit 530.

In the illustrated embodiments, the HBM device 500 further includes features to help transport the heat away from the upper surface 523a of the thermoelectric die 520. For example, the memory die 540 includes one or more thermal TSVs 542 (two illustrated in the cross-section of FIG. 5A) that are thermally coupled to the metallization structures 528 via one or more conductive structures 550 (and/or direct metal-metal bonds). Similar to the thermal TSVs 439 of FIG. 4, the thermal TSVs 542 can be thermally and electrically isolated from other structures in the memory die 540 (e.g., memory circuits, signal TSVs, and/or the like) and provide a direct travel path (e.g., along heat path H) for heat through the memory die 540 (and each other memory die in the die stack). Further, the thermoelectric die 520 includes one or more metallization structures 528 at the upper surface 523a and thermally coupled to the thermal bridge regions 538. The metallization structures 528 can include one or more route lines and/or heat spreaders that help transport heat between the thermal bridge regions 538 and the thermal TSVs 542. As a result, for example, the metallization structures 528 can reduce a need for vertical alignment between features of the thermoelectric circuit 530 and the thermal TSVs 542. In turn, the components of the thermoelectric circuit 530 can be positioned where they will be most effective (e.g., directly over the PHY and/or in other thermal hotspots) while the thermal TSVs 542 can be positioned in any available spaces in the memory die 540.

During operation of the HBM device 500, the base die 510 can provide a drive current to the thermoelectric circuit along the current path C via the first and second power TSVs 514-524. As the drive current flows from the second elements 534 to the first elements 532, the Peltier effect heat is generated at the first side 531a of the thermoelectric circuit 530 and absorbed at the second side 531b of the thermoelectric circuit 530. Said another way, the thermoelectric circuit 530 delivers active cooling at the second side 531b while emitting heat at the first side 531a. Further, the first and second power TSVs 514-524 thermally couple the second side 531b to the base die 510 (and heat-generating elements therein, such as the PHY) while the metallization structures 528 thermally couple the first side 531a to the thermal TSVs 542 in the memory die 540. As a result, the active cooling from the thermoelectric circuit 530 can transport heat from the base die 510 (e.g., heat from the PHY) to the thermal TSVs 542. The thermal TSVs 542, in turn, can then transport the heat away from the base die 510, along the heat path H, through the memory die 540.

As a result, the thermal TSVs 542 transport the heat out of the HBM device 500 via dedicated thermal pathways. Further, because the thermal TSVs 542 are isolated (e.g., spaced apart and/or insulated from) from the memory circuits in the memory die 540, the thermal TSVs 542 transport the heat along the heat path H without requiring the heat to move through the memory circuits. That is, the thermoelectric circuit 530 and the thermal TSVs 542 reduce the amount of heat from the PHY in the base die 510 that reaches the memory circuits in the memory die 540 (and each other memory die in the die stack), thereby reducing the operating temperature of the memory dies in the HBM device 500. As a result, the thermoelectric circuit 530 and the thermal TSVs 542 can help reduce the deleterious effects of heat discussed above. Further, by providing active cooling to the base die 510, the thermoelectric circuit 530 and the thermal TSVs 542 can reduce the operating temperature of the base die 510, thereby further helping reduce the deleterious effects of heat discussed above.

In some embodiments, the thermal TSVs 542 are generally similar to the signal TSVs that establish communication paths in the HBM device (e.g., the signal TSVs 436 of FIG. 4). In some embodiments, however, the thermal TSVs 542 have slight modifications to help improve the functionality of the thermal TSVs 542 as isolated heat paths. For example, as further illustrated in FIG. 5A, the thermal TSVs 542 can include a thermally conductive material 544 (e.g., a metal, such as copper, nickel, gold, and/or the like, and/or any other suitable material). The thermally conductive material 544 has a first cross-sectional width W₁ (e.g., a first cross-sectional diameter) that can be larger than the cross-sectional width (e.g., a second cross sectional diameter) of any of the signal TSVs (and/or any of the first and second power TSVs 514-524) in the HBM device 500. The relatively large cross-sectional width can help reduce thermal resistance in the thermal TSVs 542 while providing a wide communication path. As a result, the thermal TSVs 542 can communicate relatively large amounts of heat away from the base die 510 to further help reduce the deleterious effects of heat discussed above. Additionally, or alternatively, the thermally conductive material 544 can be surrounded by an insulation material 546 (e.g., various different oxide layers) that helps thermally (and electrically) isolate the thermally conductive material 544 from any other component of the memory die 540. Still further, in the illustrated embodiments, the insulation material 546 has a second cross-sectional width W₂ that can be larger than the cross-sectional width of an insulation material around any of the signal TSVs (and/or around any of the first and second power TSVs 514-524). Said another way, the thickness of the insulation material 546 can be greater than the thickness of an insulation material around any of the signal TSVs. The relatively large cross-sectional width of the insulation material 546 can further help thermally isolate the thermally conductive material 544 in the thermal TSVs 542 from any other component of the memory die 540, thereby helping prevent the heat moving along the heat path H from leaking into the memory die 540.

FIG. 5B is a partially schematic top, cross-sectional view illustrating additional details on the thermoelectric die 520 of FIG. 5A in accordance with embodiments of the present technology. In the illustrated embodiments, the thermoelectric die 520 includes a first region R₁, a second region R₂, and a third region R₃. The first region R₁ includes a plurality of signal TSVs 525 formed therein. As a result, the first region R₁ of the thermoelectric die 520 is reserved to support and/or avoid affecting the functionality of the HBM device (e.g., by interfering with and/or forming a thermal short with the TSVs 525).

The second and third regions R₂, R₃ correspond to regions of the memory dies (e.g., the memory die 540 of FIG. 5A) that will include memory circuits and/or metallization lines coupling the memory circuits to the signal TSVs 525. In some embodiments, as illustrated with respect to the second region R₂, the regions corresponding to the memory circuits are also reserved to support and/or avoid affecting the functionality of the HBM device. Such embodiments can help avoid directing heat to and/or generating heat at a location directly beneath the memory circuits to help reduce the amount of heat that is communicated to the memory circuits. In some embodiments, as illustrated with respect to the third region R₃, the regions corresponding to the memory circuits are utilized for extra space for arrays (e.g., rows, columns, and/or more complicated arrays) of the thermoelectric circuit 530. The arrays can then be thermally coupled to one or more metallization layers (e.g., the metallization structures 528 of FIG. 5A) to direct heat from the thermoelectric circuit 530 away from the regions corresponding to the memory circuits. Such embodiments can help maximize the heat-managing functionality that the thermoelectric die 520 provides to the HBM device.

As further illustrated in FIG. 5B, each of the arrays of the thermoelectric circuit 530 includes repeating regions of the first and second elements 532-534, with adjacent pairs of the first and second elements 532-534 thermally and electrically coupled by bridge regions 536. Further, a first bridge region 536a separates adjacent pairs of like elements (e.g., adjacent pairs of the first element 532 and/or adjacent pairs of the second element 534) while a second bridge region 536b separates adjacent pairs of different elements (e.g., with the first element 532 a first side of the second bridge region 536b and the second element 534 on a second side opposite the first side). Each of the first bridge regions 536a can be coupled to a power TSV (e.g., the power TSV 524 of FIG. 5A) to receive power into and/or communicate power out of the thermoelectric circuit 530. Each of the second bridge regions 536b, in contrast, can be thermally coupled to a thermal TSV (e.g., the thermal TSVs 542 of FIG. 5A). In some embodiments, the second bridge regions 536b are thermally coupled to the thermal TSVs via one or more metallization layers (e.g., the metallization structures 528 of FIG. 5A).

Although FIG. 5B illustrates the thermoelectric circuit 530 formed in every available space in the thermoelectric die 520 outside of the first and second regions second regions R₁, R₂, it will be understood that the technology disclosed herein is not so limited. For example, the thermoelectric circuit 530 can be formed only in targeted regions of the thermoelectric die 520, such as areas that are vertically aligned with the PHY in the base die and/or other hot spots in the base die. The targeted positioning can provide a balance between the heat-managing functionality of the thermoelectric die 520 and manufacturing and/or operating costs associated with the thermoelectric die 520.

Additionally, or alternatively, each array of the thermoelectric circuit 530 is operable independently from the other arrays. In some embodiments, the arrays of the thermoelectric circuit 530 are operated in an as-needed basis. For example, in some embodiments none of the arrays of the thermoelectric circuit 530 are operated while an operating temperature of the HBM device (and/or of the base die and/or memory dies more specifically) is below a first predetermined threshold. That is, the thermoelectric circuit 530 can be inactive while the operating temperature of the HBM device is sufficiently low to reduce the power consumption of the HBM device. A first subset of the arrays of the thermoelectric circuit 530 (e.g., arrays aligned with the PHY in the base die) can then be operated when the operating temperature of the HBM device crosses the first predetermined threshold to begin providing active cooling for the HBM device. A second subset of the arrays of the thermoelectric circuit 530 can be operated when the operating temperature of the HBM device crosses a second predetermined threshold to provide extra active cooling to the HBM device. The tiered approach to engaging the thermoelectric circuit 530 to provide active cooling can also help reduce the power consumption of the HBM device while providing a large amount of cooling power when needed (e.g., during complex computations).

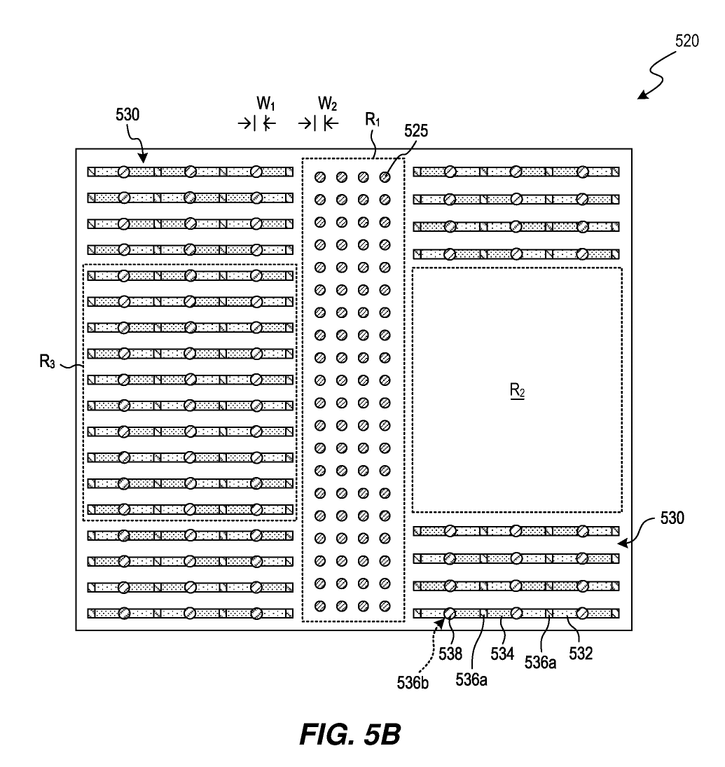

FIG. 6 is a partially schematic cross-sectional diagram of a portion of an HBM device 600 illustrating details of a thermoelectric circuit 630 in accordance with further embodiments of the present technology. In the illustrated embodiments, the HBM device 600 (and the thermoelectric circuit 630 therein) is generally similar to the HBM device 500 (and the thermoelectric circuit 530 therein) discussed above with reference to FIG. 5A. For example, the HBM device 600 includes a base die 610, a thermoelectric die 620 carried by the base die 610, and a memory die 640 carried by the thermoelectric die 620. The thermoelectric circuit 630 is formed in a base substrate 622 of the thermoelectric die 620. For example, the thermoelectric circuit 630 includes an array of one or more first elements 632 (two shown in the cross-section of FIG. 6) and one or more second elements 634 (two shown in the cross-section of FIG. 6), as well as bridge regions 636 formed between each adjacent pair of the first elements 632 and/or the second elements 634. Further, the first elements 632 are regions of the base substrate 622 that are doped with a first type of semiconductor material (e.g., doped with an n-type semiconductor material), the second elements 634 are regions of the base substrate 622 that are doped with a second type of semiconductor material (e.g., doped with a p-type semiconductor material), and the bridge regions 636 include a thermally and electrically conductive material. As a result, the first and second elements 632, 634 can form thermocouple pairs.

In the illustrated embodiments, however, the thermoelectric die 620 is configured to receive power for the thermoelectric circuit through the memory die 640 while providing active cooling to the base die 610. As a result, for example, the bridge regions 636 between adjacent pairs of like elements (e.g., a pair of the first elements 632 or a pair of the second elements 634) are coupled to one or more conductive structures 628 (e.g., a segment of a power TSV, one or more metallization layers and/or the like) to establish a thermally and electrically conductive pathway to an upper surface 623a of the thermoelectric die 620. The conductive structures 628, in turn, are coupled to thermal TSVs 642 formed in the memory die 640 by one or more conductive structures 650 (e.g., solder structures, microbumps, conductive pillars, and/or the like) and/or direct metal-metal bonds.

The thermal TSVs 642 can be generally similar to the thermal TSVs 542 discussed above with reference to FIG. 5A. For example, the thermal TSVs can include a conductive material 644 that helps establish the heat path H through the memory die 640, as well as an insulating material 646 surrounding the conductive material 644 that can help thermally isolate the thermal TSVs 642. In the illustrated embodiments, however, the thermal TSVs 642 (sometimes also referred to herein as “power-thermal TSVs”) can also supply power to the thermoelectric circuit 630 (e.g., via one or more power TSVs and/or route lines in the memory die 640), for example along the current path C.

As further illustrated in FIG. 6, the thermoelectric circuit 630 can further include thermal bridge regions 638 (one illustrated in the cross-section of FIG. 6) each thermally coupled to a corresponding one of the bridge regions 636 that is positioned between an adjacent pair of the first and second elements 632-634 (e.g., a thermocouple pair). The thermal bridge regions 638 can include a thermally conductive and electrically non-conductive material, thereby allowing the thermal bridge regions 638 to communicate heat without leaking current from the thermoelectric circuit 630. Further, each of the thermal bridge regions 638 can be thermally coupled to a thermal TSV 624 formed in the thermoelectric die 620. In turn, the thermal TSVs 624 are each coupled to a bond site 626 at the lower surface 623b of the thermoelectric die 620 and the bond sites 626 are each coupled to a corresponding bond site 615 on the base die 610 (e.g., via a conductive structure 650, a metal-metal bond, and/or the like).

During operation of the HBM device 600, heat generated in the base die 610 (e.g., by the PHY) can be communicated to the thermoelectric circuit 630 via the thermal TSVs 624 in the thermoelectric die 620. When a current is applied to the thermoelectric circuit 630 along the current path C, the thermoelectric circuit 630 can help transport the heat from a second side 631b of the thermoelectric circuit 630 (e.g., from the thermal TSVs 624 in the thermoelectric die 620) to an first side 631a of the thermoelectric circuit 630 (and into the thermal TSVs 642 in the memory die 640). As a result, the second side 631b of the thermoelectric circuit 630 can absorb heat from the base die 610 while emitting heat into the thermal TSVs 642. That is, the thermoelectric circuit 630 can provide active cooling to the base die 610 while expelling heat through the thermal TSVs 642 in the memory die 640.

As still further illustrated in FIG. 6, the bond sites 615 on the base die 610 can be coupled to one or more metallization layers 616 formed in the base die 610. The metallization layers 616 can include various route lines, thermal TSVs, and/or other heat spreading components to help move heat from a hot spot in the base die 610 (e.g., the PHY and/or another heat generator) to the bond sites 615 (and the thermal TSVs 624 in the thermoelectric die 620). In some embodiments, the thermoelectric circuit 630 of the thermoelectric die 620 is vertically aligned with the heat generating components in the base die 610. In some such embodiments, the base die 610 does not include the metallization layers 616. For example, the bond sites 615 on the base die 610 can be directly thermally coupled to the heat generating components, thereby eliminating a need for a heat spreading component.

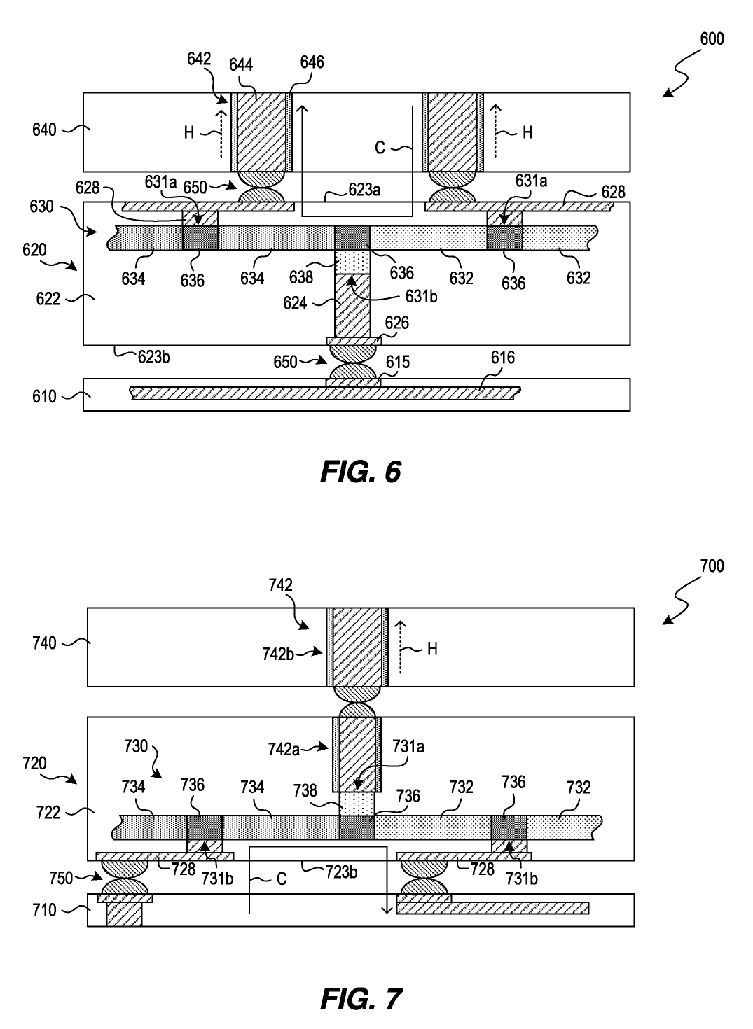

FIG. 7 is a partially schematic cross-sectional diagram of a portion of an HBM device 700 illustrating details of a thermoelectric circuit 730 in accordance with further embodiments of the present technology. In the illustrated embodiments, the HBM device 700 (and the thermoelectric circuit 730 therein) is generally similar to the HBM devices (and the thermoelectric circuits therein) discussed above with reference to FIGS. 5A–6. For example, the HBM device 700 includes a base die 710, a thermoelectric die 720 carried by the base die 710, and a memory die 740 carried by the thermoelectric die 720. The thermoelectric circuit 730 is formed in a base substrate 722 of the thermoelectric die 720. For example, the thermoelectric circuit 730 includes an array of one or more first elements 732 (two shown in the cross-section of FIG. 7) and one or more second elements 734 (two shown in the cross-section of FIG. 7), as well as bridge regions 736 formed between each adjacent pair of the first elements 732 and/or the second elements 734. Further, the first elements 732 can include a first type of semiconductor material (e.g., doped with an n-type semiconductor material), the second elements 734 can include a second type of semiconductor material (e.g., doped with a p-type semiconductor material), and the bridge regions 736 can include a thermally and electrically conductive material. As a result, the first and second elements 732, 734 can form thermocouple pairs. Still further, similar to the embodiments discussed above with reference to FIG. 5A, the thermoelectric circuit 730 is configured to receive power directly from the base die 710.

In the illustrated embodiments, however, the thermoelectric die 720 is attached to the base die 710 in a face-to-face arrangement (e.g., with the thermoelectric circuit formed adjacent to a lower surface 723b of the thermoelectric die 720). As a result, for example, the bridge regions 736 between adjacent pairs of like elements (e.g., a pair of the first elements 732 or a pair of the second elements 734) can be coupled to one or more conductive structures 728 (e.g., one or more metallization layers and/or the like) to establish a thermally and electrically conductive pathway to the lower surface 723b of the thermoelectric die 720. The conductive structures 728, in turn, can be coupled to metallization structures (e.g., power TSVs, metallization layers, and/or the like) in the base die 710 by one or more conductive structures 750 (e.g., solder structures, microbumps, conductive pillars, and/or the like) and/or direct metal-metal bonds.

As further illustrated in FIG. 7, the thermoelectric circuit 730 can include thermal bridge regions 738 (one illustrated in the cross-section of FIG. 7) each thermally coupled to a corresponding one of the bridge regions 736 that is positioned between an adjacent pair of the first and second elements 732-734 (e.g., a thermocouple pair ). The thermal bridge regions 738 can include a thermally conductive and electrically non-conductive material, thereby allowing the thermal bridge regions 738 to communicate heat without leaking current from the thermoelectric circuit 730. Further, each of the thermal bridge regions 738 can be thermally coupled to a first segment 742a of a thermal TSV 742. In various embodiments, the first segment 742a (e.g., a first individual segment) in the thermoelectric die 720 can be coupled to a second segment 742b of the thermal TSV 742 in the memory die 740 by one or more conductive structures (e.g., solder structures, microbumps, conductive pillars, and/or the like) and/or metal-metal bonds. As a result, the thermal TSV 742 can communicate heat away from the thermoelectric circuit along the heat path H.

During operation, the HBM device 700 can direct a current through the thermoelectric circuit 730 (e.g., along the current path C). In response, the thermoelectric circuit 730 can transport heat from a second side 731b of the thermoelectric circuit 730 to a first side 731a of the thermoelectric circuit 730 (and into the thermal TSV 742). As a result, the second side 731b of the thermoelectric circuit 730 can absorb heat from the base die 710 while emitting heat into the thermal TSVs 742. Said another way, the thermoelectric circuit 730 can provide active cooling to the base die 710 while expelling heat through the thermal TSVs 742.

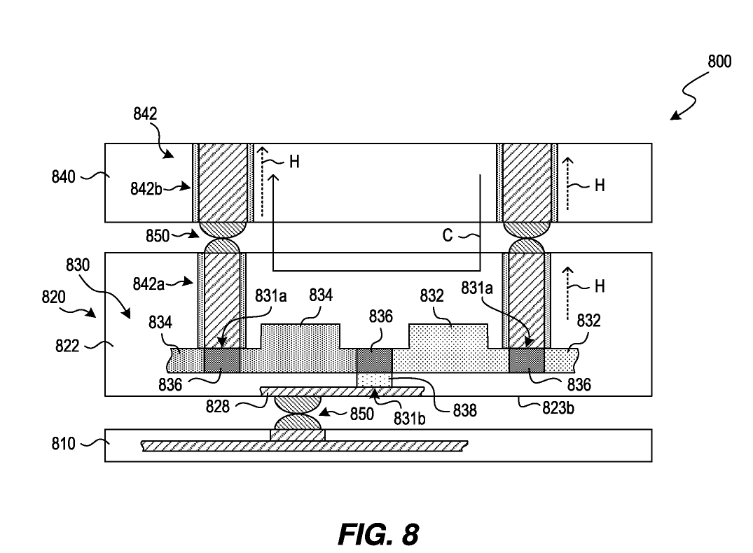

FIG. 8 is a partially schematic cross-sectional diagram of a portion of an HBM device 800 illustrating details of a thermoelectric circuit 830 in accordance with further embodiments of the present technology. In the illustrated embodiments, the HBM device 800 (and the thermoelectric circuit 830 therein) is generally similar to the HBM devices (and the thermoelectric circuits therein) discussed above with reference to FIGS. 5A–7. For example, the HBM device 800 includes a base die 810, a thermoelectric die 820 carried by the base die 810, and a memory die 840 carried by the thermoelectric die 820. The thermoelectric circuit 830 is formed in a base substrate 822 of the thermoelectric die 820. Further, the thermoelectric circuit 830 includes an array of one or more first elements 832 (two shown in the cross-section of FIG. 8) and one or more second elements 834 (two shown in the cross-section of FIG. 8), as well as bridge regions 836 formed between each adjacent pair of the first elements 832 and/or the second elements 834. Still further, the first elements 832 can include a first type of semiconductor material (e.g., doped with an n-type semiconductor material), the second elements 834 can include a second type of semiconductor material (e.g., doped with a p-type semiconductor material), and the bridge regions 836 can include a thermally and electrically conductive material. As a result, the first and second elements 832-834 can form thermocouple pairs.

Similar to the embodiments discussed above with reference to FIG. 7, the thermoelectric die 820 is attached to the base die 810 in a face-to-face configuration. In the illustrated embodiments, however, the thermoelectric circuit 830 is configured to receive power through the memory die 840. As a result, for example, the bridge regions 836 between adjacent pairs of like elements (e.g., a pair of the first elements 832 or a pair of the second elements 834) can each be coupled to a first segment 842a of a thermal TSV 842. The first segments 842a can then be coupled to second segments 842b of the thermal TSVs 842 formed in the memory die 840 via conductive structures 850 (e.g., solder structures, microbumps, conductive pillars, and/or the like) and/or metal-metal bonds. As a result, the thermal TSVs 842 can establish the heat path H away from the base die 810. Further, thermal TSVs 842 (sometimes also referred to herein as “power-thermal TSVs”) can be coupled to one or more power TSVs and/or route lines in the memory die 840 (and/or another memory die in the die stack) to supply power to the thermoelectric circuit 830 (e.g., along the current path C).

As further illustrated in FIG. 8, the thermoelectric circuit 830 can further include thermal bridge regions 838 (one illustrated in the cross-section of FIG. 8) each thermally coupled to a corresponding one of the bridge regions 836 that is positioned between an adjacent pair of the first and second elements 832-834 (e.g., a thermocouple pair). The thermal bridge regions 838 can include a thermally conductive and electrically non-conductive material, thereby allowing the thermal bridge regions 838 to communicate heat without leaking current from the thermoelectric circuit 830. Further, each of the thermal bridge regions 838 can be thermally coupled to one or more conductive structures 828 (e.g., one or more metallization layers and/or the like) to establish a thermally and electrically conductive pathway to the lower surface 823b of the thermoelectric die 820. The conductive structures 828, in turn, can be coupled to metallization structures (e.g., power TSVs, metallization layers, and/or the like) in the base die 810 by one or more conductive structures 850 (e.g., solder structures, microbumps, conductive pillars, and/or the like) and/or direct metal-metal bonds.

Similar to the discussion above, during operation, the HBM device 800 can direct a current through the thermoelectric circuit 830 (e.g., along the current path C). In response, the thermoelectric circuit 830 can transport heat from a second side 831b of the thermoelectric circuit 830 to a first side 831a of the thermoelectric circuit 830 (and into the thermal TSVs 842). As a result, the second side 831b of the thermoelectric circuit 830 can absorb heat from the base die 810 while emitting heat into the thermal TSVs 842. That is, the thermoelectric circuit 830 can provide active cooling to the base die 810 while expelling heat through the thermal TSVs 842.

In various embodiments, components of the thermoelectric circuit 830 can be configured to help increase the amount of thermal transportation provided by the thermoelectric circuit 830 (e.g., the volume of heat that is communicated through the thermoelectric circuit 830). For example, in the embodiments illustrated ion FIG. 8, the first and second elements 832-834 are formed via trenching techniques, resulting in a u-shaped cross section. The trenching can increase the volume of the n-type semiconductor material and p-type semiconductor material for each thermocouple pair without increasing the longitudinal footprint required for the thermocouple pair (and therefore the thermoelectric die 820). By increasing the volume of the p-type and n-type semiconductor materials, the trenching can help increase the amount of heat transported by each of the thermocouple pairs. Said another way, the trenching can help increase the size of the thermal gradient that the thermoelectric circuit 830 can create, thereby increasing the cooling power that the thermoelectric die 820 can provide. It will be understood that similar trenching can occur for each of the first and second elements 832-834 and/or for the bridge regions 836 between thermocouple pairs. Further, it will be understood that, although illustrated and discussed with respect to the embodiments of FIG. 8, each of the embodiments discussed herein can include similar trenching configurations for the first and second elements 832-834 and/or for the bridge regions 836 between thermocouple pairs.

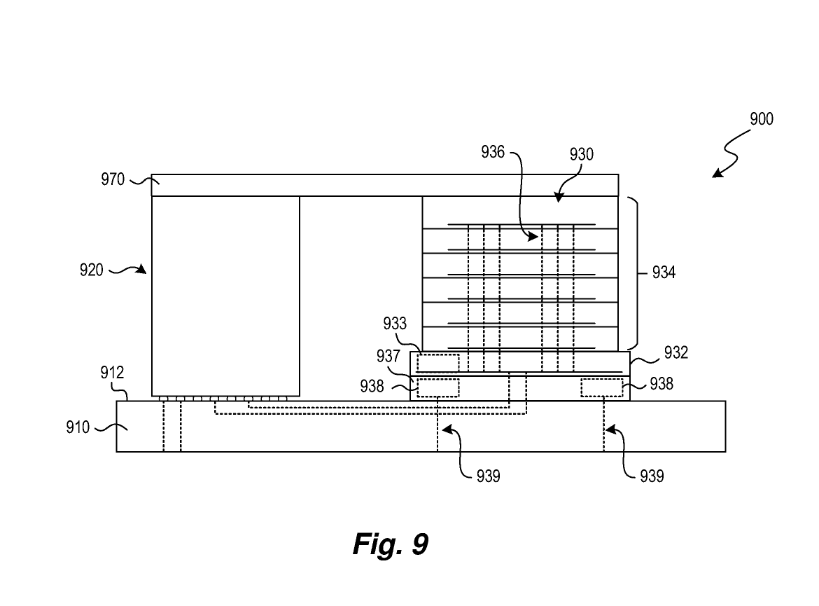

FIG. 9 is a partially schematic cross-sectional diagram of a SiP device 900 configured in accordance with embodiments of the present technology. As illustrated in FIG. 9, the SiP device 900 is generally similar to the SiP device 400 discussed above with reference to FIG. 4. For example, as illustrated in FIG. 9, the SiP device 900 includes a base substrate 910, a processing device 920 and an HBM device 930 each integrated with an upper surface 912 of the base substrate 910, and a thermal lid 970 carried by the processing device 920 and the HBM device 930. Further, the HBM device 930 includes a base die 932, one or more memory dies 934 (six illustrated in the cross-section of FIG. 9), and a thermoelectric die 937 thermally coupled to the base die 932. The base die 932 includes a PHY 933 that is communicably coupled to each of the memory dies 934 (sometimes referred to collectively herein as a “memory die stack,” a “stack of memory dies,” and/or the like) via a plurality of signal TSVs 936 (e.g., an HBM bus). Similar to the discussion above, each of the signal TSVs 936 in the HBM bus can include a segment in each of the memory dies 934 that are coupled together via a plurality of bonding features (e.g., bond sites (e.g., copper pads, gold-plated pads, exposed pads, and/or the like) bonded via metal-metal bonds, solder structures (e.g., solder balls, solder pillars, and/or the like), and/or the like) between corresponding segments of the signal TSVs 936 in the memory dies 934.

In the illustrated embodiments, however, the thermoelectric die 937 is positioned between the base die 932 and the base substrate 910. Similar to the discussion above, the thermoelectric die 937 can include one or more thermoelectric circuits 938 (two illustrated in the cross-section of FIG. 9) formed directly into (e.g., integrated with) the substrate of the thermoelectric die 937. In the illustrated embodiments, however, the thermoelectric circuits 938 can receive power directly from the base substrate 910 and/or from the base die 932. Additionally, or alternatively, the thermoelectric circuits 938 can expel heat through and one or more thermal TSVs 939 (two illustrated in the cross-section of FIG. 9) formed into the base substrate 910. That is, rather than directing heat to the thermal lid 970, the thermoelectric circuits 938 can expel heat through the bottom (e.g., the backside) of the base substrate 910. As a result, the thermoelectric circuits 938 can transport heat from the base die 932 (e.g., away from the PHY 933) into the thermal TSVs 939 and the thermal TSVs 939 can then transport the heat to through the base substrate 910. As a result, the thermoelectric die 937 can provide active cooling to the base die 932 to help counter and/or mitigate the heat generated by heat-generating areas of the base die 932, such as the PHY 933. In turn, the thermoelectric die 937 can help reduce and/or mitigate the thermal buildup in the HBM device 930, and memory dies 934 therein, during operation of the SiP device 900. In some embodiments, the thermoelectric circuits 938 can have a larger footprint when the thermoelectric die 937 is beneath the base die 932 as compared to when the thermoelectric die 937 is on top of the base die 932 (e.g., as illustrated in FIG. 4). The additional footprint can be available, for example, since the thermoelectric circuits 938 do not need to avoid overlap with memory circuits.

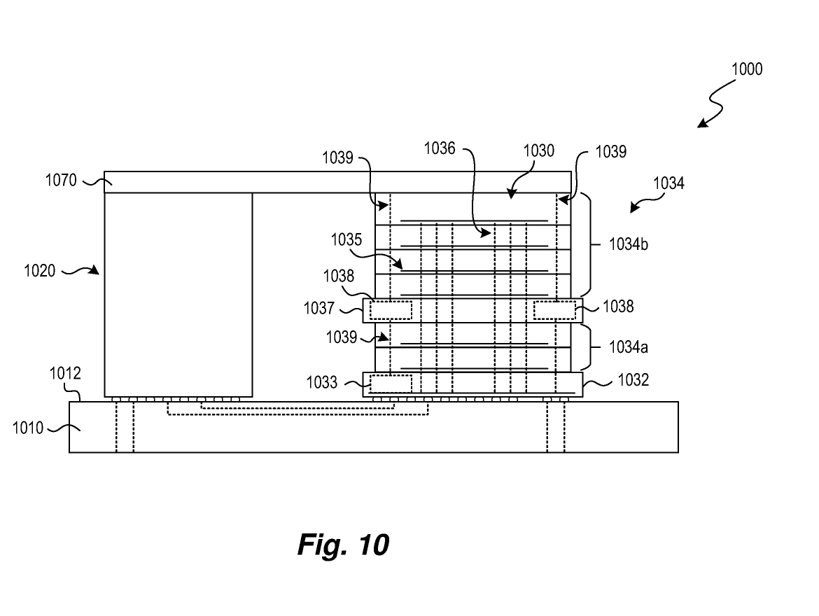

FIG. 10 is a partially schematic cross-sectional diagram of a SiP device 1000 configured in accordance with embodiments of the present technology. As illustrated in FIG. 10, the SiP device 1000 is generally similar to the SiP devices 400, 900 discussed above with reference to FIGS. 4 and 9. For example, as illustrated in FIG. 10, the SiP device 1000 includes a base substrate 1010, a processing device 1020 and an HBM device 1030 each integrated with an upper surface 1012 of the base substrate 1010, and a thermal lid 1070 carried by the processing device 1020 and the HBM device 1030. Further, the HBM device 1030 includes a base die 1032, one or more memory dies 1034 (six illustrated in the cross-section of FIG. 10), and a thermoelectric die 1037 thermally coupled to the base die 1032. The base die 1032 includes a PHY 1033 that is communicably coupled to each of the memory dies 1034 (sometimes referred to collectively herein as a “memory die stack,” a “stack of memory dies,” and/or the like) via a plurality of signal TSVs 1036 (e.g., an HBM bus). Similar to the discussion above, each of the signal TSVs 1036 in the HBM bus can include a segment in each of the memory dies 1034 that are coupled together via a plurality of bonding features (e.g., bond sites (e.g., copper pads, gold-plated pads, exposed pads, and/or the like) bonded via metal-metal bonds, solder structures (e.g., solder balls, solder pillars, and/or the like), and/or the like) between corresponding segments of the signal TSVs 1036 in the memory dies 1034. Still further, the thermoelectric die 1037 can include one or more thermoelectric circuits 1038 (two illustrated in FIG. 10) formed directly into (e.g., integrated with) the substrate of the thermoelectric die 1037.

In the illustrated embodiments, however, the thermoelectric die 1037 is stacked on top of a first subset of the memory dies 1034a while a second subset of the memory dies 1034b is stacked on top of the thermoelectric die 1037. That is, as illustrated in FIG. 10, the thermoelectric die 1037 can be spaced apart from the base die 1032 by one or more of the memory dies 1034 (spaced apart by two of the memory dies 1034 in FIG. 10). In some embodiments, the memory circuits 1035 are coupled to the base die 1032 (e.g., to the PHY 1033 and/or one or more metallization layers in the base die 1032) by a first segment of thermal TSVs 1039 that extends through the first subset of the memory dies 1034a. In some embodiments, the thermoelectric circuits 1038 are thermally coupled to one or more of the first subset of the memory dies 1034a. In each of the embodiments above, the thermoelectric circuits 1038 can then be coupled to the thermal lid 1070 by a second segment of thermal TSVs 1039 that extends through the second subset of the memory dies 1034b. As a result, the thermoelectric circuits 1038 can absorb heat from the base die 1032 and/or the first subset of the memory dies 1034a and expel the heat into the second segment of the thermal TSVs 1039. The second segment of the thermal TSVs 1039 can then transport the heat to the thermal lid 1070. Said another way, the thermoelectric die 1037 can provide active cooling to the base die 1032 and/or the first subset of the memory dies 1034a to help counter and/or mitigate the heat generated by heat-generating areas of the base die 1032, such as the PHY 1033. In turn, the thermoelectric die 1037 can help reduce and/or mitigate the thermal buildup in the HBM device 1030, and memory dies 1034 therein, during operation of the SiP device 1000.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, that various components and functions of the technology may be combined and integrated, and/or that various components of the present technology can be rearranged. In a specific, non-limiting example, the HBM device can include a first thermoelectric die that is positioned beneath the base die (e.g., between the base die and a base substrate of a SiP device) as discussed above with reference to FIG. 9, as well as a second thermoelectric die carried by the base die as discussed above with reference to FIG. 4. In this example, the combination of thermoelectric dies can provide two sources of active cooling to the base die, thereby further helping mitigate heat generation therein. In another specific, non-limiting example, the HBM device can include a first thermoelectric die that is carried by the base die as discussed above with reference to FIG. 4, and a second thermoelectric die that is carried by a subset of the memory dies as discussed above with reference to FIG. 10. In such embodiments, the first thermoelectric die can provide active cooling to the base die while the second thermoelectric die provides active cooling to a subset of the memory dies closest to the base die (and therefore most affected by heat generated therein). In yet another, related example, the HBM device can include multiple thermoelectric dies carried on top of subsets of the memory dies. In such embodiments, each of the thermoelectric dies can provide active cooling to a corresponding subset of the memory dies. In yet another example, the thermoelectric circuits disclosed herein can be integrated into other semiconductor substrates in the stacked semiconductor devices. In a specific, non-limiting example, the thermoelectric circuits disclosed herein can be formed directly into the semiconductor substrates in the base die of the HMB device and/or directly into one or more of the memory dies in the HBM stack. Still further, it will be understood that certain aspects of the technology described in the context of particular embodiments may also be combined or eliminated in other embodiments. Purely y way of example, as discussed above, although semiconductor elements with trenching features are discussed in the context of FIG. 8, it will be understood that a thermoelectric circuit having similar features can be implemented in any of the embodiments discussed above with reference to FIGS. 4–10 to help increase the amount of cooling provided by the thermoelectric die.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor device, comprising:
a first semiconductor die;
a second semiconductor die carried by the first semiconductor die, wherein the second semiconductor die comprises a first through substrate via (TSV) and a plurality of second TSVs spaced apart from the first TSV; and
a thermoelectric die carried by the first semiconductor die beneath the second semiconductor die, the thermoelectric die comprising:
a thermoelectric circuit having a first side thermally coupled to the first semiconductor die and a second side thermally coupled to the first TSV such that, when a current is applied to the thermoelectric circuit, the thermoelectric circuit moves heat from the first semiconductor die into the first TSV to provide active cooling to the first semiconductor die,
wherein each of the second TSVs extends through the thermoelectric die to electrically couple the second semiconductor die to the first semiconductor die through the thermoelectric die, and wherein each of the second TSVs is spaced apart from the thermoelectric circuit.

2. The stacked semiconductor device of claim 1, further comprising a third semiconductor die carried by the first semiconductor die beneath the thermoelectric die, wherein each of the second TSVs extends through and is electrically coupled to the third semiconductor die.

3. The stacked semiconductor device of claim 1 wherein the first semiconductor die is a base die of a high-bandwidth memory device, wherein the second semiconductor die is a first memory die of stack of memory dies carried by the base die, and wherein the plurality of TSVs extend through each memory die in the stack of memory dies to electrically couple each of the memory dies to the base die.

4. The stacked semiconductor device of claim 1 wherein the thermoelectric circuit comprises:
a first element formed in a base substrate of the thermoelectric die, wherein the first element comprises an n-type semiconductor material;
a second element formed in the base substrate of the thermoelectric die, wherein the second element comprises a p-type semiconductor material; and
a bridge region formed in the base substrate and coupling the first element to the second element, the bridge region comprising a thermally and electrically conductive material.

5. The stacked semiconductor device of claim 4 wherein one or more of the bridge region, the first element, and/or the second element comprises a nanowire structure.

6. The stacked semiconductor device of claim 4 wherein the thermoelectric die further comprises:
a metal layer formed on the second side of the thermoelectric die, wherein the metal layer is thermally coupled to the first TSV; and
a thermal bridge region thermally coupling the bridge region to the metal layer, wherein the thermal bridge region comprises a thermally conductive and electrically non-conductive material,
wherein the thermoelectric circuit further comprises a plurality of third TSVs formed in the base substrate of the thermoelectric die, wherein the plurality of third TSVs extend from the first side to a corresponding one of the first element and the second element.

7. The stacked semiconductor device of claim 4 wherein the thermoelectric die further comprises:
a thermal bridge region thermally coupled to the bridge region, wherein the thermal bridge region comprises a thermally conductive and electrically non-conductive material; and
a third TSV extending from the first side of the thermoelectric die to the thermal bridge region,
wherein:
the first TSV is two first TSVs; and
the thermoelectric circuit further comprises a plurality of metallization structures individually coupling the first element and the second element to respective ones of the two first TSVs.

8. The stacked semiconductor device of claim 4 wherein the thermoelectric die further comprises:
a segment of the first TSV extending from the second side of the thermoelectric die toward the first side; and
a thermal bridge region thermally coupling the bridge region to the segment of the first TSV, wherein the thermal bridge region comprises a thermally conductive and electrically non-conductive material,
wherein the thermoelectric circuit further comprises a plurality of metallization structures individually coupling the first element and the second element to bond sites at the first side of the thermoelectric die.

9. The stacked semiconductor device of claim 4 wherein:
the first TSV is two first TSVs;
the thermoelectric die further comprises:
a metal layer formed on the first side of the thermoelectric die, wherein the metal layer is thermally coupled to the first semiconductor die die; and
a thermal bridge region thermally coupling the bridge region to the metal layer, wherein the thermal bridge region comprises a thermally conductive and electrically non-conductive material; and
the thermoelectric circuit further comprises individual segments of the two first TSVs formed in the base substrate of the thermoelectric die, wherein a first segment extends from the second side of the thermoelectric die to the first element, and wherein a second first segment extends from the second side of the thermoelectric die to the second element.

10. The stacked semiconductor device of claim 1 wherein the thermoelectric circuit comprises:
an array of a plurality of first elements and a plurality of second elements formed in a base substrate of the thermoelectric die, wherein each of the plurality of first elements includes an n-type semiconductor material, and wherein each of the plurality of second elements includes a p-type semiconductor material; and
a plurality of bridge regions formed in the base substrate between adjacent pairs of the plurality of first elements and the plurality of second elements, wherein each of the plurality of bridge regions comprises a thermally and electrically conductive material to couple the adjacent pairs.

11. The stacked semiconductor device of claim 1 wherein the first TSV has a first cross-sectional diameter, and wherein each of the plurality of second TSVs has a second cross-sectional diameter smaller than the first cross-sectional diameter.

12. A thermoelectric semiconductor die for providing active cooling to a stack of semiconductor dies, the thermoelectric semiconductor die comprising:
a base substrate; and
a thermoelectric circuit formed into the base substrate, the thermoelectric circuit comprising:
a first element formed in the base substrate of the thermoelectric die, wherein the first element comprises a first region of the base substrate doped with an n-type semiconductor material;
a second element formed in the base substrate of the thermoelectric die, wherein the second element comprises a second region of the base substrate doped with a p-type semiconductor material; and
a bridge region formed in the base substrate between the first element and the second element, wherein the bridge region thermally and electrically couples the first element to the second element to form a thermocouple pair.

13. The thermoelectric semiconductor die of claim 12 wherein the thermoelectric circuit further comprises a thermal bridge region thermally coupled between an upper surface of the base substrate and the bridge region, wherein the thermal bridge region comprises an electrically non-conductive material.

14. The thermoelectric semiconductor die of claim 13, further comprising a segment of a thermal through substrate via (TSV) extending between the upper surface of the base substrate and the thermal bridge region.

15. The thermoelectric semiconductor die of claim 12 wherein the thermoelectric circuit further comprises a thermal bridge region thermally coupled between a lower surface of the base substrate and the bridge region, wherein the thermal bridge region comprises an electrically non-conductive material.

16. The thermoelectric semiconductor die of claim 15, further comprising a segment of a thermal through substrate via (TSV) extending between the lower surface of the base substrate and the thermal bridge region.

17. The thermoelectric semiconductor die of claim 12, further comprising a plurality of through substrate via (TSV) segments extending from a lower surface of the base substrate to an upper surface of the base substrate opposite the lower surface, wherein each of the plurality of TSV segments is spaced apart from the thermoelectric circuit.

18. A system-in-package device, comprising:
a base substrate;
a processing unit integrated with the base substrate; and
a high-bandwidth memory device integrated with the base substrate and electrically coupled to the processing unit through the base substrate, wherein the high-bandwidth memory device comprises:
a base die;
a thermoelectric die carried by the base die, the thermoelectric die comprising a thermoelectric circuit having a first side thermally coupled to the base die and a second side opposite the first side, wherein the thermoelectric circuit is configured to transport heat from the first side to the second side in response to an input current;
a stack of memory dies carried by the thermoelectric die;
a first through substrate via (TSV), the first TSV thermally coupled between the second side of the thermoelectric circuit and an upper surface of the stack of memory dies; and
a plurality of second TSVs, each of the plurality of second TSVs extending from the base die to an uppermost memory die in the stack of memory dies.

19. The system-in-package device of claim 18 wherein the first TSV is thermally and electrically isolated from each of the plurality of second TSVs.

20. The system-in-package device of claim 18 wherein:
the thermoelectric die comprises a first region dedicated to a lower portion of the plurality of second TSVs and a second region vertically aligned with memory circuits in the stack of memory dies; and
the thermoelectric circuit is formed in a base material of the thermoelectric die spaced apart from the first region and the second region.
